(19) United States
(12) Patent Application Publication
(10) Pub. No.: US 2017/0256496 A1
(43) Pub. Date: Sep. 7, 2017

(54) CHIP PACKAGE AND METHOD FOR FORMING THE SAME

(71) Applicant: XINTEC INC., Taoyuan City (TW)

(72) Inventors: Chia-Sheng LIN, Taoyuan City (TW); Chaung-Lin LAI, Taoyuan City (TW); Kuei-Wei CHEN, Keelung City (TW)

(21) Appl. No.: 15/440,442

(22) Filed: Feb. 23, 2017

Related U.S. Application Data
(60) Provisional application No. 62/301,795, filed on Mar. 1, 2016.

(51) Int. Cl. H01L 23/538; H01L 21/48; H01L 23/31; H01L 23/00

(52) U.S. Cl. CPC H01L 23/5389; H01L 24/05; H01L 21/486; H01L 23/5384; H01L 23/3171; H01L 21/4853; H01L 2924/19102; H01L 2924/301; H01L 2924/146; H01L 27/14621

(57) ABSTRACT

A chip package including a substrate is provided. A sensing region or device region of the substrate is electrically connected to a conducting pad. A first insulating layer is disposed on the substrate. A redistribution layer is disposed on the first insulating layer. A first portion and a second portion of the redistribution layer are electrically connected to the conducting pad. A second insulating layer conformally extends on the first insulating layer, and covers side surfaces of the first portion and the second portion. A protection layer is disposed on the second insulating layer. A portion of the second insulating layer is located between the protection layer and the first insulating layer. A method of forming the chip package is also provided.

### CROSS REFERENCE TO RELATED APPLICATIONS

This application claims priority of U.S. Provisional Application No. 62/301,795, filed Mar. 1, 2016 the entirety of which is incorporated by reference herein.

### BACKGROUND OF THE INVENTION

Field of the Invention

The invention relates to chip package technology, and in particular to a chip package and methods for forming the same.

Description of the Related Art

The chip packaging process is an important step in the fabrication of an electronic product. Chip packages not only protect the chips therein from outer environmental contaminants, but they also provide electrical connection paths between electronic elements inside and those outside of the chip packages. For example, chip packages have conductive lines to form conductive paths. As electronic products gradually develop towards miniaturization, the size of chip packages is gradually reduced.

However, when the size of chip packages is reduced, the thickness and width of the conductive lines become smaller. The pitch between the conductive lines also becomes narrower. As a result, circuit failure may easily occur in a region having densely arranged conductive lines. For example, electromigration and/or the Galvanic effect may be induced between two of the conductive lines that are made of metal. This may result in problems such as a short circuit and/or an open circuit being induced. Therefore, the quality of and reliability of the chip packages is reduced.

Thus, there exists a need in the art for development of a chip package and methods for forming the same capable of mitigating or eliminating the aforementioned problems.

### BRIEF SUMMARY OF THE INVENTION

Embodiments of the invention provide a chip package including a substrate. The substrate includes a sensing region or device region electrically connected to a conducting pad. The chip package also includes a first insulating layer on the substrate. The chip package further includes a first redistribution layer on the first insulating layer. A first portion and a second portion of the first redistribution layer are electrically connected to the conducting pad. In addition, the chip package includes a second insulating layer. The second insulating layer conformally extends on the first insulating layer and covers side surfaces of the first portion and the second portion. The chip package also includes a protection layer on the second insulating layer. A portion of the second insulating layer is located between the protection layer and the first insulating layer.

Embodiments of the invention provide a chip package including a substrate. The substrate includes a sensing region or device region electrically connected to a conducting pad. The chip package also includes a first insulating layer on the substrate. The chip package further includes a first redistribution layer on the first insulating layer. A first portion of the first redistribution layer is electrically connected to the conducting pad. In addition, the chip package includes a second redistribution layer. A first portion of the second redistribution layer is located on the first portion of the first redistribution layer. A second portion of the second redistribution layer is in direct contact with the first insulating layer.

Embodiments of the invention provide a method for forming a chip package. The method includes providing a substrate. The substrate includes a sensing region or device region electrically connected to a conducting pad. The method also includes forming a first insulating layer on the substrate. The method further includes forming a second redistribution layer on the first insulating layer. A first portion and a second portion of the second redistribution layer are electrically connected to the conducting pad. In addition, the method includes forming a second insulating layer. The second insulating layer conformally extends on the first insulating layer and covers side surfaces of the first portion and the second portion of the second redistribution layer. The method also includes forming a protection layer on the second insulating layer. A portion of the second insulating layer is located between the protection layer and the first insulating layer.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIGS. 1A to 1F are cross-sectional views of some exemplary embodiments of a method for forming a chip package according to the invention.

FIGS. 2A to 2C are cross-sectional views of some exemplary embodiments of a method for forming a chip package according to the invention.

FIG. 3 is a cross-sectional view of some exemplary embodiments of a chip package according to the invention.

### DETAILED DESCRIPTION OF THE INVENTION

The making and using of the embodiments of the present disclosure are discussed in detail below. However, it should be noted that the embodiments provide many applicable inventive concepts that can be embodied in a variety of specific methods. The specific embodiments discussed are merely illustrative of specific methods to make and use the embodiments, and do not limit the scope of the disclosure. The disclosed contents of the present disclosure include all the embodiments derived from claims of the present disclosure by those skilled in the art. In addition, the present disclosure may repeat reference numbers and/or letters in the various embodiments. This repetition is for the purpose of simplicity and clarity, and does not imply any relationship between the different embodiments and/or configurations discussed. Furthermore, when a first layer is referred to as being on or overlying a second layer, the first layer may be in direct contact with the second layer, or spaced apart from the second layer by one or more material layers.

A chip package according to an embodiment of the present invention may be used to package micro-electro-mechanical system chips. However, embodiments of the invention are not limited thereto. For example, the chip package of the embodiments of the invention may be implemented to package active or passive devices or electronic components of integrated circuits, such as digital or analog circuits. For example, the chip package is related to optoelectronic devices, micro-electro-mechanical systems (MEMS), biometric devices, microfluidic systems, and physical sensors measuring changes to physical quantities such as heat, light, capacitance, pressure, and so on. In particular, a wafer-level package (WSP) process may optionally be used to package semiconductor chips, such as image-sensor elements, light-emitting diodes (LEDs), solar cells, RF circuits, accelerators, gyroscopes, fingerprint-recognition devices, microactuators, surface acoustic wave devices, pressure sensors, ink printer heads, and so on.

The aforementioned wafer-level packaging process mainly means that after the packaging step is accomplished during the wafer stage, the wafer with chips is cut to obtain individual packages. However, in a specific embodiment, separated semiconductor chips may be redistributed on a carrier wafer and then packaged, which may also be referred to as a wafer-level packaging process. In addition, the aforementioned wafer-level packaging process may also be adapted to form a chip package having multilayer integrated circuit devices by stacking a plurality of wafers having integrated circuits or to form a system-in-package (SIP).

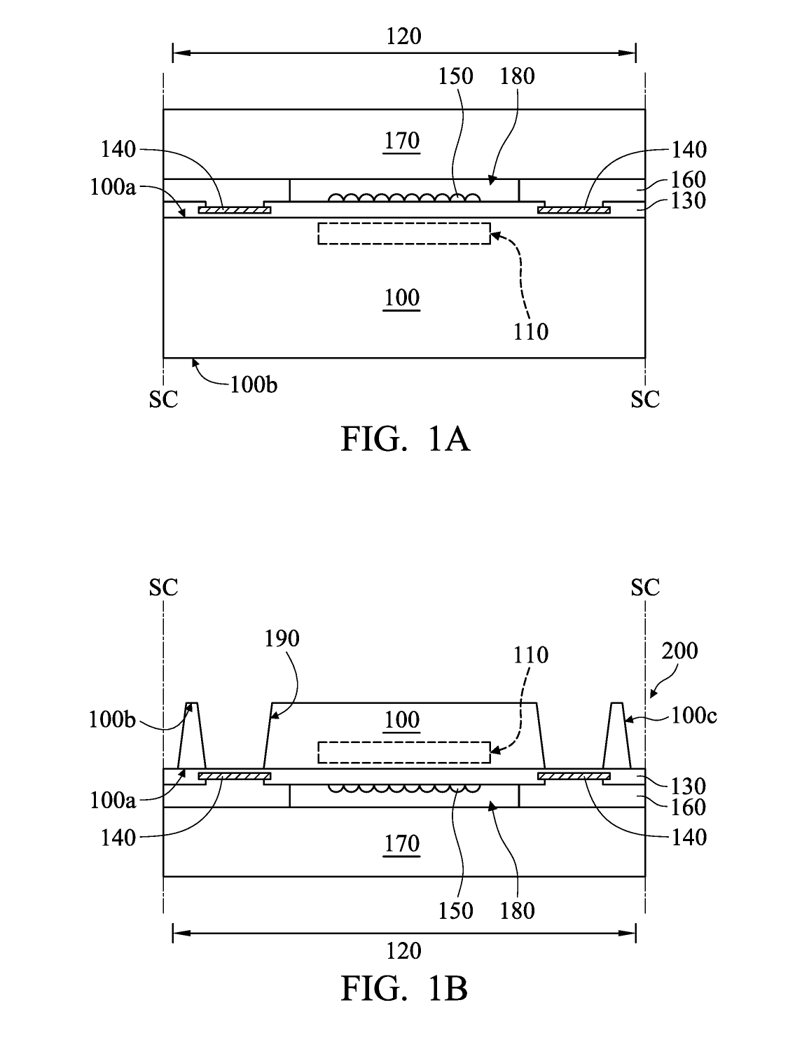

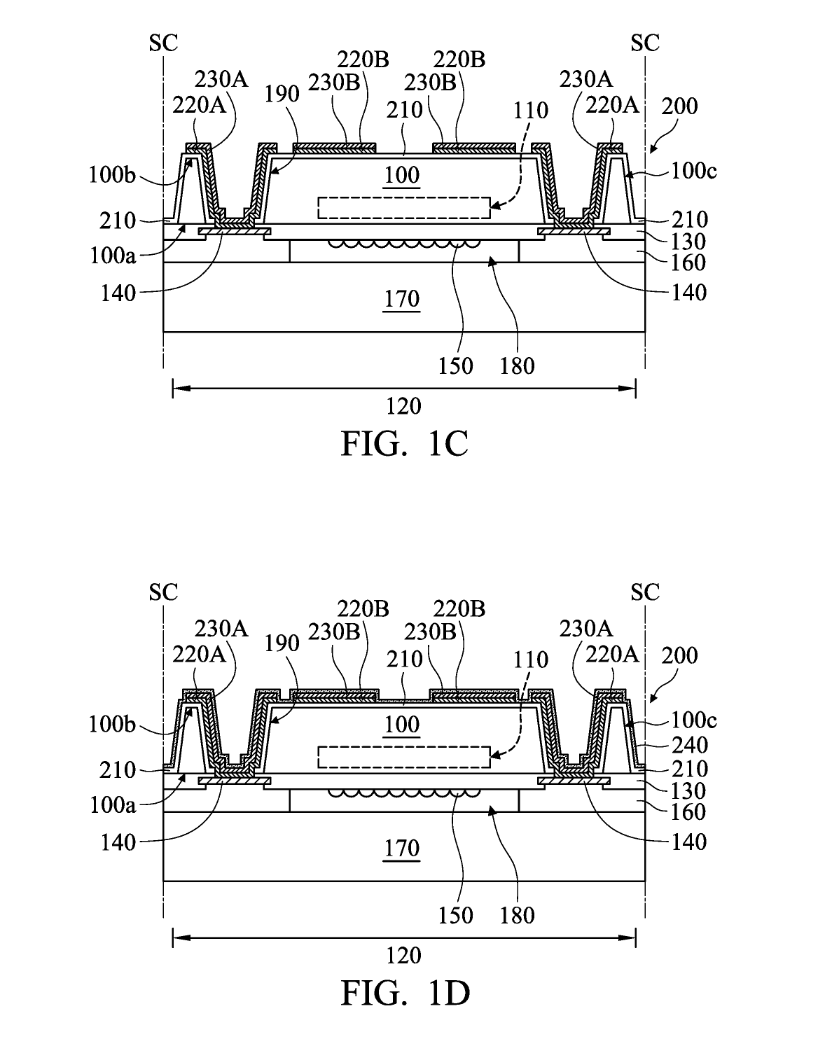

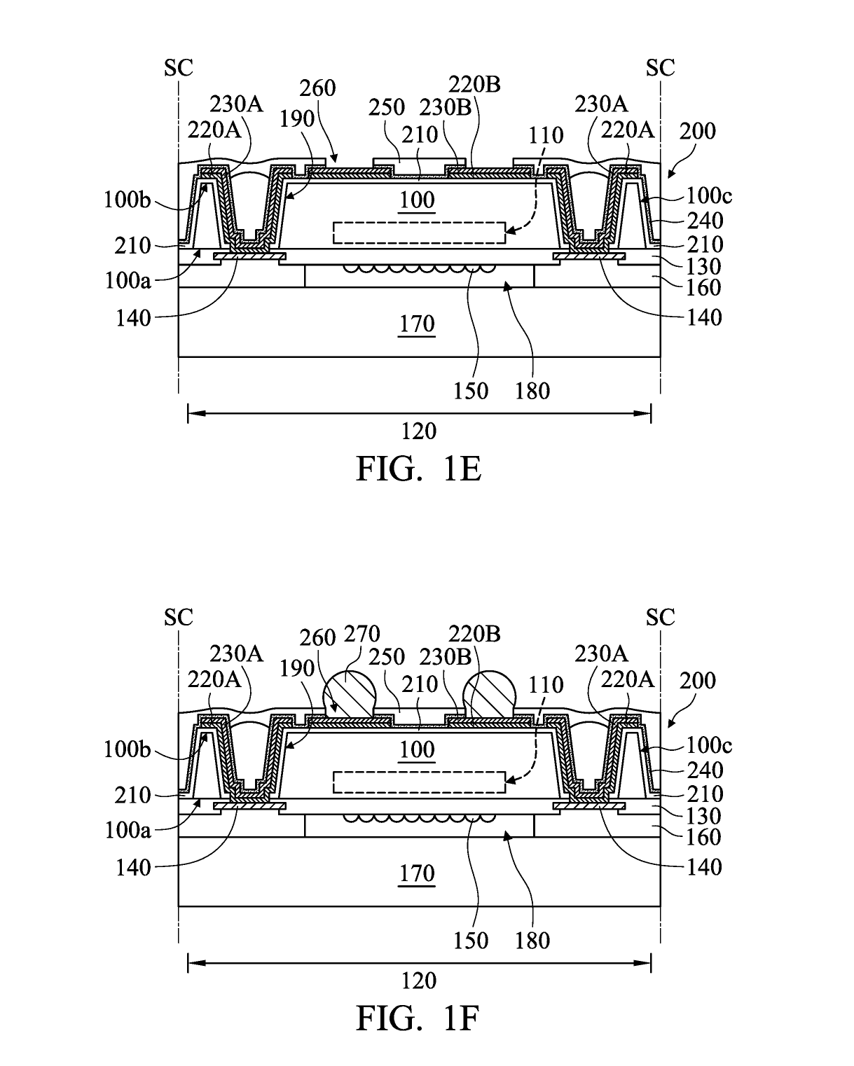

Some exemplary embodiments of a method for forming a chip package according to the invention are illustrated in FIGS. 1A to 1F. FIGS. 1A to 1F are cross-sectional views of some exemplary embodiments of a method for forming a chip package according to the invention.

Referring to FIG. 1A, a substrate 100 is provided. The substrate 100 has a front surface 100a and a back surface 100b, and comprises multiple chip regions 120. To simplify the diagram, only a complete chip region 120 and a partial chip region 120 adjacent thereto are depicted herein. In some embodiments, the substrate 100 is a silicon substrate or another semiconductor substrate. In some embodiments, the substrate 100 is a silicon wafer so as to facilitate the wafer-level packaging process.

There is an insulating layer 130 on the front surface 100a of the substrate 100. In general, the insulating layer 130 may be made of an interlayer dielectric (ILD) layer, inter-metal dielectric (IMD) layers and a covering passivation layer. To simplify the diagram, only a single insulating layer 130 is depicted herein. In some embodiments, the insulating layer 130 comprises an inorganic material, such as silicon oxide, silicon nitride, silicon oxynitride, metal oxide, a combination thereof, or another suitable insulating material.

In some embodiments, one or more conducting pads 140 are in the insulating layer 130 in each of the chip regions 120. In some embodiments, the conducting pads 140 may be a single conducting layer or comprise multiple conducting layers. To simplify the diagram, only a single conducting layer is depicted herein as an example. In some embodiments, the insulating layer 130 in each of the chip regions 120 comprises one or more openings exposing the corresponding conducting pads 140.

In some embodiments, a sensing region or device region 110 is in each of the chip regions 120. The sensing region or device region 110 may be adjacent to the insulating layer 130 and the front surface 100a of the substrate 100. The sensing region or device region 110 may be electrically connected to the conducting pads 140 through interconnection structures (not shown). The interconnection structures comprise various conductive features, such as conductive lines (or traces), conductive vias, and conductive plugs (or contacts).

The sensing region or device region 110 comprises a sensing element or another suitable electronic element. In some embodiments, the sensing region or device region 110 comprises a light-sensing element or another suitable optoelectronic element. In some other embodiments, the sensing region or device region 110 comprises a sensing element which is configured to sense biometrics (such as a fingerprint-recognition element), or a sensing element which is configured to sense environmental characteristics (such as a temperature-sensing element, a humidity-sensing element, a pressure-sensing element or a capacitance-sensing element) or another suitable sensing element.

In some embodiments, the aforementioned structure is fabricated by sequentially performing a front-end process and a back-end process of a semiconductor device. For example, the sensing region or device region 110 may be formed in the substrate 100 during the front-end process. The insulating layer 130, the interconnection structures, and the conducting pads 140 may be formed on the substrate 100 during the back-end process. In other words, the following method for forming a chip package proceeds to subsequent packaging processes on the aforementioned structure after the back-end process is completed.

In some embodiments, an optical element 150 is disposed on the front surface 100a of the substrate 100 in each of the chip regions 120 and corresponds to the sensing region or device region 110. In some embodiments, the optical element 150 is a micro-lens array, a color filter layer, a combination thereof, or another suitable optical element. In some other embodiments, there is no optical element 150 disposed on the front surface 100a of the substrate 100.

Afterwards, a spacer layer (or dam) 160 is formed on a cover plate 170. The cover plate 170 is bonded to the front surface 100a of the substrate 100 through the spacer layer 160. The spacer layer 160 form a cavity 180 between the substrate 100 and the cover plate 170 in each of the chip regions 120. As a result, the optical element 150 is located in the cavity 180. The cover plate 170 protects the optical element 150 in the cavity 180. In some other embodiments, the spacer layer 160 is formed on the front surface 100a of the substrate 100, and the cover plate 170 is subsequently bonded to the substrate 100.

In some embodiments, the cover plate 170 comprises glass, aluminium nitride (AlN), or another suitable transparent material. In some other embodiments, there is no optical element disposed on the front surface 100a of the substrate 100, and the cover plate 170 comprises a semiconductor material or another suitable non-transparent material. In some embodiments, the cover plate 170 is a temporary substrate and is removed in a subsequent process.

In some embodiments, the spacer layer 160 does not substantially absorb moisture. In some embodiments, the spacer layer 160 may be non-adhesive, and the cover plate 170 is attached on the substrate 100 through an adhesive layer. In some other embodiments, the spacer layer 160 may itself be adhesive. The cover plate 170 can be attached to the substrate 100 by the spacer layer 160 so the spacer layer 160 may contact none of the adhesion glue, thereby assuring that the spacer layer 160 will not move due to the disposition of the adhesion glue. Furthermore, since adhesion glue is not needed, the optical element 150 can be prevented from being contaminated by an overflow of adhesion glue. In some other embodiments, the spacer layer 160 is replaced with an adhesive layer, and there is no cavity 180 formed between the substrate 100 and the cover plate 170.

In some embodiments, the spacer layer 160 is formed by a deposition process (such as a coating process, a physical vapor deposition process, a chemical vapor deposition process, or another suitable process). In some embodiments, the spacer layer 160 comprises epoxy resin, inorganic materials (such as silicon oxide, silicon nitride, silicon oxynitride, metal oxide or a combination thereof), organic polymer materials (such as polyimide, butylcyclobutene (BCB), parylene, polynaphthalenes, fluorocarbons or acrylates), or another suitable insulating material. Alternatively, the spacer layer 160 may comprise a photoresist material, and may be patterned by exposure and developing processes to expose the optical element 150.

Referring to FIG. 1B, a thinning process (such as an etching process, a milling process, a grinding process or a polishing process) using the temporary cover plate 170 as a carrier substrate is performed on the back surface 100b of the substrate 100. As a result, the thickness of the substrate 100 is reduced.

Afterwards, multiple first openings 190 and a second opening 200 may be formed in the substrate 100 in each of the chip regions 120. The first openings 190 and the second opening 200 expose the insulating layer 130 from the back surface 100b of the substrate 100. In some embodiments, the first openings 190 and the second opening 200 are simultaneously formed in the substrate 100 by a lithography process and an etching process (such as a dry etching process, a wet etching process, a plasma etching process, a reactive ion etching process, or another suitable process). In some other embodiments, the first openings 190 may be formed by a notching process, while the second opening 200 may be formed by lithography and etching processes.

In some embodiments, the first openings 190 correspond to the conducting pads 140 and penetrate the substrate 100. In some embodiments, the diameter of the first openings 190 adjacent to the front surface 100a is less than the diameter of the first openings 190 adjacent to the back surface 100b. Therefore, the first openings 190 have sidewalls that are inclined to the front surface 100a and the back surface 100b. As a result, the difficulty of the process for subsequently forming layers in the first openings 190 is reduced, and reliability is improved. For example, since the diameter of the first openings 190 adjacent to the front surface 100a is less than the diameter of the first openings 190 adjacent to the back surface 100b, layers (such as an insulating layer and a redistribution layer) that are subsequently formed in the first openings 190 can be easily deposited on a corner between the first openings 190 and the insulating layer 130 to avoid affecting electrical connection paths or inducing problems with leakage current.

In some embodiments, the second opening 200 is a trench. The second opening 200 extends along the scribe lines SC between the adjacent chip regions 120 and penetrates the substrate 100. As a result, portions of the substrate 100 in the chip regions 120 are separated from each other. In some embodiments, the diameter of the second opening 200 adjacent to the front surface 100a is less than the diameter of the second opening 200 adjacent to the back surface 100b. Therefore, the second opening 200 has inclined side surfaces. In other words, the substrate 100 in each of the chip regions 120 has inclined side surfaces 100c.

In some embodiments, multiple openings 190 in two adjacent chip regions 120 are arranged apart along the second opening 200. The first openings 190 and the second opening 200 are spaced apart and completely isolated from each other by a portion of the substrate 100 (such as a sidewall portion).

In some embodiments, the second opening 200 extends along the chip regions 120 and continuously surrounds the first openings 190. In some other embodiments, the first openings 190 and the second opening 200 communicate with each other. For example, a portion of the first openings 190 adjacent to the back surface 100b and a portion of the second opening 200 adjacent to the back surface 100b communicate with each other. As a result, the substrate 100 has a sidewall portion that is lower than the back surface 100b. In other words, the thickness of this sidewall portion is less than the thickness of the substrate 100. In some embodiments, since the first openings 190 and the second opening 200 communicate with each other without being completely isolated from each other through a portion of the substrate 100, it is possible to avoid the buildup of stress in the substrate 100 between the first openings 190 and the second opening 200. Stress can be mitigated and released through the second opening 200. As a result, the sidewall portions of the substrate 100 are prevented from cracking.

Referring to FIG. 1C, a first insulating layer 210 may be formed on the back surface 100b of the substrate 100 by a deposition process (such as a coating process, a physical vapor deposition process, a chemical vapor deposition process or another suitable process). The first insulating layer 210 fills the first openings 190 and the second opening 200. In some embodiments, the first insulating layer 210 is conformally deposited on the sidewalls and the bottoms of the first openings 190 and the second opening 200.

In some embodiments, the first insulating layer 210 comprises epoxy resin, inorganic materials (such as silicon oxide, silicon nitride, silicon oxynitride, metal oxide or a combination thereof), organic polymer materials (such as polyimide, butylcyclobutene (BCB), parylene, polynaphthalenes, fluorocarbons or acrylates) or another suitable insulating material.

Afterwards, portions of the first insulating layer 210 on the bottom of the first openings 190 and the underlying insulating layer 130 are removed by lithography and etching processes. As a result, the first openings 190 extend further into the insulating layer 130 and expose the corresponding conducting pads 140.

Thereafter, one or more patterned redistribution layers are formed on the first insulating layer 210 by a deposition process (such as a coating process, a physical vapor deposition process, a chemical vapor deposition process, an electroplating process, an electroless plating process or another suitable process) and lithography and etching processes. In some embodiments, a first redistribution layer includes a first portion 220A and a second portion 220B that are electrically connected to each other. A second redistribution layer includes a first portion 230A and a second portion 230B that are electrically connected to each other.

In some embodiments, the first redistribution layer and the second redistribution layer have substantially the same circuit pattern. For example, the first portion 220A completely overlaps the first portion 230A, and the second portion 220B completely overlaps the second portion 230B. In other words, the side surface of the first portion 220A is coplanar with the side surface of the first portion 230A, and the side surface of the second portion 220B is coplanar with the side surface of the second portion 230B.

In some other embodiments, the first redistribution layer and the second redistribution layer have similar circuit patterns. The first portion 230A may cover or wrap the side and top surfaces of the first portion 220A, and the second portion 230B may cover the side and top surfaces of the second portion 220B. As a result, the first portion 230A and the second portion 230B extend to contact the first insulating layer 210.

The thicknesses of the first redistribution layer and the second redistribution layer may be the same or different. For example, the thickness of the first redistribution layer may be less than the thickness of the second redistribution layer. In some other embodiments, the patterned redistribution layer is a single redistribution layer. Alternatively, the patterned redistribution layer may include three or more redistribution layers.

In some embodiments, the first portion 220A and the first portion 230A are located on the sidewalls and bottom of the first openings 190. For example, the first portion 220A and the first portion 230A extend conformally on the sidewalls and bottom of the first openings 190 to electrically connect to the conducting pads 140. The first portion 220A and the first portion 230A also extend from the inside of the first openings 190 to the back surface 100b of the substrate 100, but the first portion 220A and the first portion 230A only partially cover the back surface 100b around the first openings 190, as shown in FIG. 1C. In some embodiments, the first portion 220A and the first portion 230A longitudinally overlap the conducting pads 140 without longitudinally overlapping the sensing region or device region 110.

In some embodiments, the second portion 220B and the second portion 230B are located above the back surface 100b of the substrate 100. For example, the second portion 220B and/or the second portion 230B are longitudinally superimposed on the sensing region or device region 110 without longitudinally overlapping the conducting pads 140. In some other embodiments, the second portion 220B and/or the second portion 230B may not longitudinally overlap the sensing region or device region 110.

In some embodiments, the first portion 220A, the second portion 220B, the first portion 230A, and the second portion 230B are electrically isolated from the substrate 100 by the first insulating layer 210. The first portion 220A and the first portion 230A may be in direct electrical contact with or indirectly electrically connected to the exposed conducting pads 140 through the first openings 190. As a result, the first portion 220A and the first portion 230A within the first openings 190 may also be referred to as a through silicon via (TSV).

In some embodiments, the first portion 220A, the second portion 220B, the first portion 230A, and the second portion 230B include aluminum, nickel, gold, copper, platinum, tin, titanium tungsten, a combination thereof, a conductive polymer material, a conductive ceramic material (such as indium tin oxide or indium zinc oxide), or another suitable conductive material. For example, the first portion 220A and the second portion 220B are made of aluminum while the first portion 230A and the second portion 230B are made of nickel. Alternatively, the first portion 220A and the second portion 220B are made of titanium tungsten while the first portion 230A and the second portion 230B are made of aluminum and/or nickel.

Referring to FIG. 1D, a second insulating layer 240 may be formed on the back surface 100b of the substrate 100 by a deposition process (such as a coating process, a physical vapor deposition process, a chemical vapor deposition process or another suitable process). The second insulating layer 240 covers the patterned first and second redistribution layers. In some embodiments, the second insulating layer 240 is in direct contact with the first insulating layer 210.

The second insulating layer 240 extends conformally on the first insulating layer 210 from the back surface 100b along the sidewalls and bottom of the first openings 190 and the second opening 200, and the second insulating layer 240 covers the side surface 100c of the substrate 100. That is, the thickness of the second insulating layer 240 on the sidewalls and bottom of the first openings 190 is substantially the same as the thickness of the second insulating layer 240 located on the sidewalls and bottom of the second opening 200. The thickness of the second insulating layer 240 on the sidewalls and bottom of the first openings 190 is also substantially the same as the thickness of the second insulating layer 240 on the back surface 100b.

In some embodiments, the second insulating layer 240 completely covers the side surfaces of the first portion 220A and the second portion 220B. The second insulating layer 240 also completely covers the side and top surfaces of the first portion 230A and the second portion 230B. In some embodiments, the first insulating layer 210 and the second insulating layer 240 commonly surround the second portion 220B and the second portion 230B.

In some embodiments, a portion of the second insulating layer 240 is laterally sandwiched between the first portion 220A and the second portion 220B. In some embodiments, a portion of the second insulating layer 240 is laterally sandwiched between two second portions 220B.

In some embodiments, the second insulating layer 240 comprises inorganic materials (such as silicon oxide, silicon nitride, silicon oxynitride, metal oxide or a combination thereof) or another suitable insulating material. The second insulating layer 240 and the first insulating layer 210 may be formed of the same material or different materials. In some embodiments, the second insulating layer 240 is formed of a material that has high insulation and does not substantially absorb moisture or is impermeable to moisture.

In some embodiments, the thickness of the second insulating layer 240 is less than the thickness of the first insulating layer 210. For example, the thickness of the first insulating layer 210 may be in a range from about 0.5 μm to about 4 μm. The thickness of the second insulating layer 240 may be in a range from about 0.2 μm to about 0.5 μm. In some embodiments, the thickness of the second insulating layer 240 is less than the thickness of the first and/or second redistribution layer. For example, the thickness of the second insulating layer 240 is less than the thickness of the second portion 220B and/or the thickness of the second portion 230B. Alternatively, the thickness of the second insulating layer 240 is less than the sum of the thicknesses of the second portion 220B and the second portion 230B.

Referring to FIG. 1E, a protection layer 250 may be formed on the back surface 100b of the substrate 100 by a deposition process. The protection layer 250 extends from the back surface 100b into the second opening 200, and covers the side surface 100c of the substrate 100. In some embodiments, the protection layer 250 is in direct contact with the second insulating layer 240.

In some embodiments, the protection layer 250 fills up the second opening 200. In some embodiments, the protection layer 250 partially fills the second opening 200 and does not completely fill the second opening 200.

In some embodiments, the protection layer 250 seals the first openings 190 but does not fill the first openings 190 so that a void (which may be referred to as an air gap, hole or cavity) is formed between the second insulating layer 240 and the protection layer 250 within the first openings 190. In some other embodiments, the protection layer 250 partially fills the first openings 190 or completely fills the first openings 190.

In some embodiments, the protection layer 250 is completely isolated from the first portion 220A, the second portion 220B, the first portion 230A, and the second portion 230B without direct contact. In some embodiments, a portion of the second insulating layer 240 is sandwiched longitudinally and/or laterally between the first portion 230A and the protection layer 250. A portion of the second insulating layer 240 is longitudinally and/or laterally sandwiched between the second portion 230B and the protection layer 250. In some embodiments, a portion of the second insulating layer 240 is laterally sandwiched between the first portion 220A and the protection layer 250. A portion of the second insulating layer 240 is laterally sandwiched between the second portion 220B and the protection layer 250.

In some embodiments, the protection layer 250 is completely separated from the first insulating layer 210 without direct contact. In some embodiments, a portion of the second insulating layer 240 is longitudinally sandwiched between the protection layer 250 and the first insulating layer 210 and laterally sandwiched between the first portion 220A and the second portion 220B.

In some embodiments, the protection layer 250 comprises epoxy resin, solder mask, inorganic materials (such as silicon oxide, silicon nitride, silicon oxynitride, metal oxide or a combination thereof), organic polymer materials (such as polyimide, butylcyclobutene, parylene, polynaphthalenes, fluorocarbons or acrylates), or another suitable insulating material.

In some embodiments, the second insulating layer 240 and the protection layer 250 are made of different materials. For example, the material of the second insulating layer 240 has better insulation than the material of the protection layer 250. Furthermore, the material of the protection layer 250 may absorb moisture while the material of the second insulating layer 240 is not moisture absorbent.

Next, one or more openings 260 may be formed in the protection layer 250 and the second insulating layer 240 on the back surface 100b of the substrate 100 by lithography and etching processes so as to partially expose the second portion 230B.

In some embodiments, the width of the openings 260 in the second insulating layer 240 is the same as the width of the openings 260 in the protection layer 250. In some other embodiments, the width of the openings 260 in the second insulating layer 240 is greater than the width of the openings 260 in the protection layer 250. For example, when the openings 260 are formed by a wet etching process, the second insulating layer 240 may be over-etched and result in an undercut.

Referring to FIG. 1F, conducting structures 270 (e.g., solder balls, bumps, or conductive pillars) may be filled in the openings 260 using an electroplating process, a screen printing process, or other suitable process. The conducting structures 270 are electrically connected to the exposed second portion 230B. In some embodiments, the conductive structures 270 include tin, lead, copper, gold, nickel, or a combination thereof.

In some embodiments, the conducting structures 270 are in direct contact with the second insulating layer 240. In some embodiments, the lower portion of the conducting structures 270 is continuously surrounded by the second insulating layer 240 and the protection layer 250. In some embodiments, another bonding layer may optionally be formed between the conducting structures 270 and the exposed second portion 230B. For example, the bonding layer may include a nickel layer, a gold layer, another suitable material layer, or a combination thereof. In some embodiments, the bonding layer is in direct contact with the second insulating layer 240, and the conducting structures 270 are separated from the second insulating layer 240.

Afterwards, the protection layer 250, the second insulating layer 240, the first insulating layer 210, the spacer layer 160, and the cover plate 170 are cut along the scribe lines SC (i.e. along the second opening 200) to form multiple independent chip packages. For example, a cutting process may be performed using a cutting tool or laser. Using a laser cutting process can avoid displacement of upper and lower layers. After the dicing, the substrate 100 and the insulating layer 130 may be considered as a chip/die.

According to the aforementioned embodiments, a second insulating layer is formed so as to completely cover the side surfaces and/or the top surface of the patterned redistribution layer. The second insulating layer has high insulating property and is effective for isolating contaminants from the outside. For example, the second insulating layer prevents moisture from permeating into the patterned redistribution layer. As a result, the electromigration phenomenon between patterns of the patterned redistribution layer can be alleviated or eliminated by the second insulating layer. Short-circuiting, which may be induced by an undesirable connection between the first redistribution layer and the second redistribution layer due to ion migration (such as nickel ion or another metal ion), is avoided. Open-circuiting, which may be induced by voids formed in the first redistribution layer and/or the second redistribution layer due to ion migration, is also avoided. Therefore, the quality and reliability of the chip package is improved.

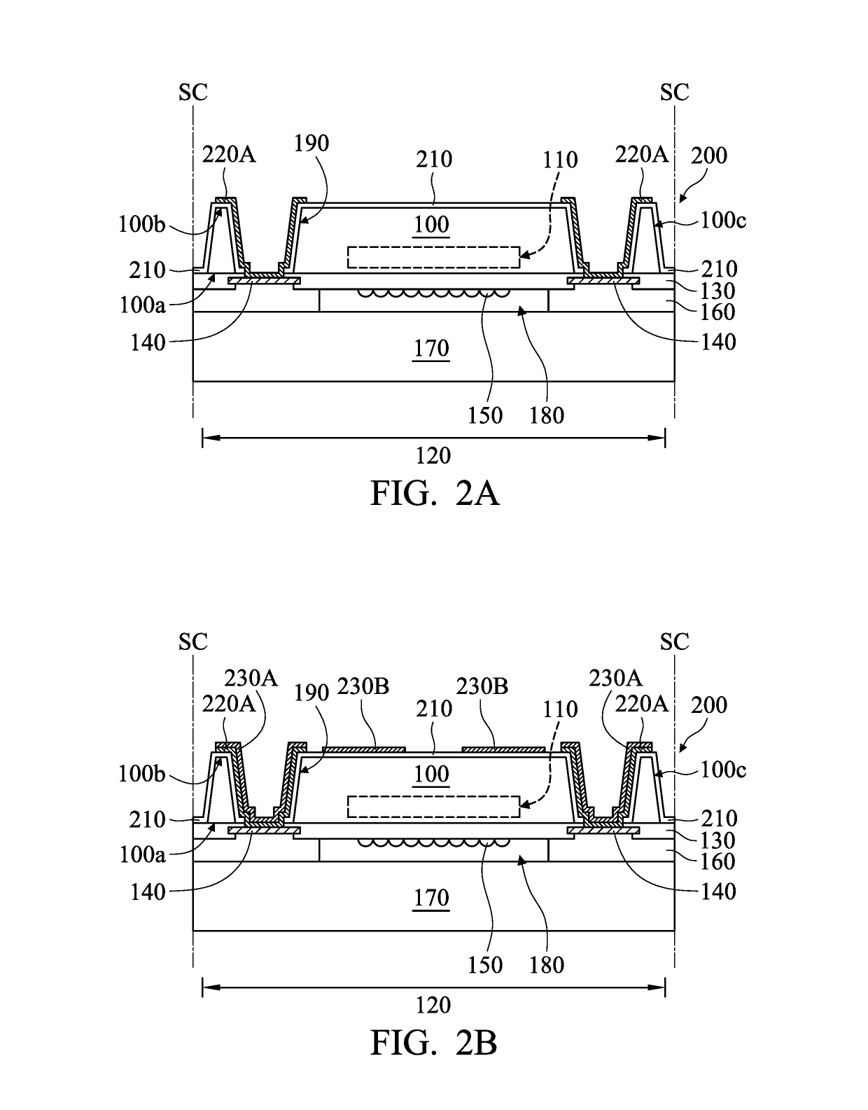

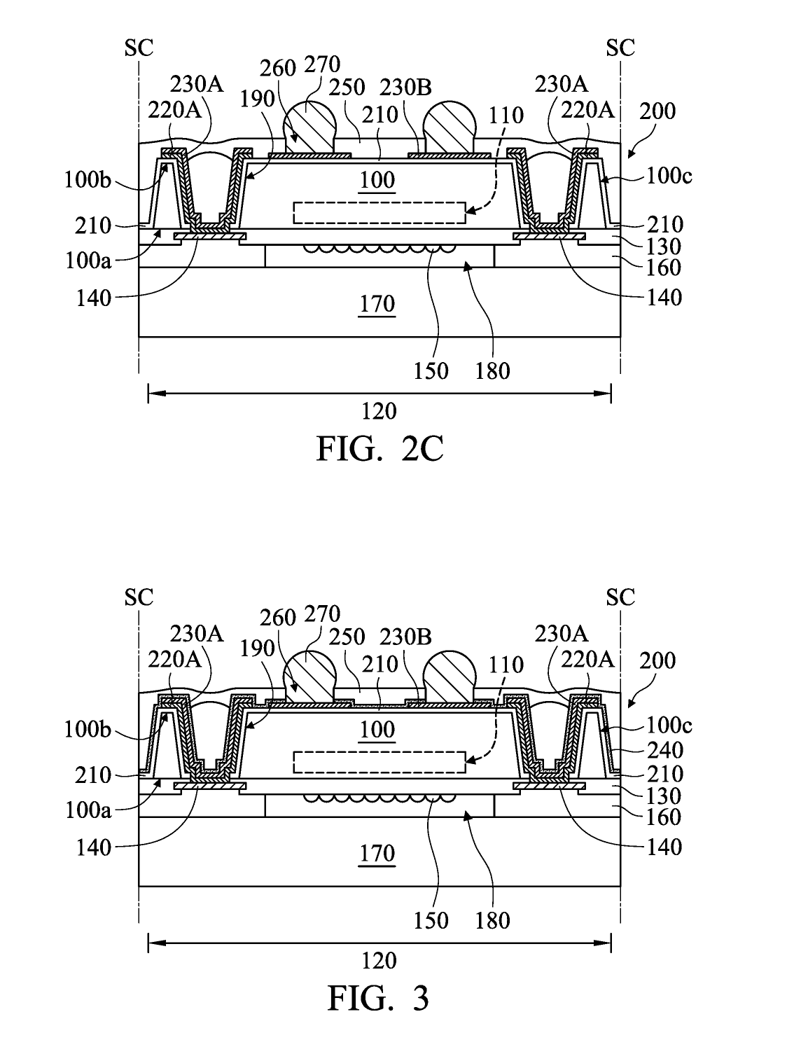

Some exemplary embodiments of a method for forming a chip package according to the invention are illustrated in FIGS. 2A to 2C. FIGS. 2A to 2C are cross-sectional views of some exemplary embodiments of a method for forming a chip package according to the invention. Elements in FIGS. 2A to 2C that are the same as those in FIGS. 1A to 1F are labeled with the same reference numbers as in FIGS. 1A to 1F and are not described again for brevity.

Referring to FIG. 2A, a structure as shown in FIG. 1B is provided. A first insulating layer 210 is formed by steps that are the same as or similar to the steps shown in FIG. 1C. Next, the first insulating layer 210 at the bottom of the first openings 190 and the underlying insulating layer 130 are removed by a lithography process and an etching process. As a result, the first openings 190 extend into the insulating layer 130 to expose the corresponding conducting pads 140.

Subsequently, a patterned first redistribution layer is formed on the first insulating layer 210 by a deposition process (such as a coating process, a physical vapor deposition process, a chemical vapor deposition process, an electroplating process, an electroless plating process or another suitable process) and lithography and etching processes. In some embodiments, the first redistribution layer includes a first portion 220A. The first redistribution layer may include a single-layer material layer or a multi-layer material layer.

In some embodiments, the first portion 220A is located on the sidewalls and the bottom of the first openings 190. For example, the first portion 220A extends conformally on the sidewalls and bottom of the first openings 190. The first portion 220A also extends from the inside of the first openings 190 to the back surface 100b of the substrate 100, but the first portion 220A only partially covers the back surface 100b around the first openings 190. In some embodiments, the first portion 220A longitudinally overlaps the conducting pads 140 without longitudinally overlapping the sensing region or device region 110.

In some embodiments, the first portion 220A includes aluminum, nickel, gold, copper, platinum, tin, titanium tungsten, a combination thereof, a conductive polymer material, a conductive ceramic material (such as indium tin oxide or indium zinc oxide), or another suitable conductive material.

In some embodiments, the first portion 220A serves as a barrier layer between the conducting pads 140 and material layers that are subsequently formed over the first portion 220A. For example, the material of the first portion 220A (e.g., titanium tungsten or another material) can prevent the material of the conducting pads 140 (e.g., copper or another material) from reacting with a subsequently formed layer of material (e.g., aluminum or another material), resulting in the migration or diffusion phenomenon. Therefore, the first portion 220A can prevent delamination between the conducting pads 140 and the subsequently formed material layer. The device performance of the chip package is also prevented from being deteriorated.

Referring to FIG. 2B, a patterned second redistribution layer is formed on the first insulating layer 210 and the first portion 220A by a deposition process (such as a coating process, a physical vapor deposition process, a chemical vapor deposition process, an electroplating process, an electroless plating process or another suitable process) and lithography and etching processes. In some embodiments, a second redistribution layer includes a first portion 230A and a second portion 230B that are electrically connected to each other. The second redistribution layer may include a single-layer material layer or a multi-layer material layer.

In some embodiments, the first portion 230A and the first portion 220A have substantially the same circuit pattern. For example, the first portion 230A completely overlaps the first portion 220A. In some other embodiments, the first portion 230A and the first portion 220A have similar circuit patterns. For example, the first portion 230A may cover or wrap the side surfaces and the top surface of the first portion 220A. As a result, the first portion 230A extends to directly contact the first insulating layer 210.

In some embodiments, the first portion 230A is located on the first portion 220A within the first openings 190. For example, the first portion 230A extends conformally on the sidewalls and the bottom of the first openings 190. The first portion 230A also extends from the inside of the first openings 190 to the back surface 100b of the substrate 100, but the first portion 230A partially covers the back surface 100b around the first openings 190. In some embodiments, the first portion 230A longitudinally overlaps the conducting pads 140 without longitudinally overlapping the sensing region or device region 110.

In some embodiments, the second portion 230B is located above the back surface 100b of the substrate 100. For example, the second portion 230B is longitudinally superimposed on the sensing region or device region 110 without longitudinally overlapping the conducting pads 140.

In some embodiments, the bottom surface of the second portion 230B is lower than the bottom surface of the first portion 230A so that the bottom surface of the second portion 230B is not coplanar with the bottom surface of the first portion 230A. In some embodiments, the bottom surface of the second portion 230B is substantially coplanar with the bottom surface of a part of the first portion 220A.

In some embodiments, the second portion 230B is in direct contact with the first insulating layer 210, while a part of the first portion 220A separates the first portion 230A from the first insulating layer 210. In some embodiments, a part of the first portion 220A is sandwiched between the first portion 230A and the first insulating layer 210, and another part of the second portion 220A is sandwiched between the first portion 230A and the conducting pads 140.

In some embodiments, the first portion 230A and the second portion 230B includes aluminum, nickel, gold, copper, platinum, tin, titanium tungsten, a combination thereof, a conductive polymer material, a conductive ceramic material (such as indium tin oxide or indium zinc oxide), or another suitable conductive material. In some embodiments, the first portion 220A is made of titanium tungsten, and the first portion 230A and the second portion 230B are made of aluminum and/or nickel.

In some cases, there is more than one redistribution layer made of different materials. As a result, the Galvanic effect may be induced between the redistribution layers due to various potential differences, resulting in a displacement reaction between different material layers. For example, the Galvanic effect may occur between a layer of titanium tungsten and a layer of nickel or another material layer, causing nickel ions to migrate or diffuse into the layer of titanium tungsten.

According to the aforementioned embodiments, the first redistribution layer includes only the first portion 220A as the barrier layer. The first redistribution layer does not have a portion formed over the sensing region or device region 110 (such as the second portion 220B shown in FIG. 1C). Accordingly, the Galvanic effect occurring between the first redistribution layer and the second redistribution layer over the sensing region or device region 110 can be avoided, thereby ensuring the electrical performance of the chip package.

In some cases, after more than one redistribution layer is deposited, the redistribution layers are etched. However, since the upper redistribution layer covers the lower redistribution layer, the removal by the etchant is carried out from only the side surface of the lower redistribution layer. As a result, it is difficult to successfully pattern the lower redistribution layer. There may be residue of the lower redistribution layer.

According to the aforementioned embodiments, the deposited first redistribution layer is etched before the second redistribution layer is deposited. The removal by the etchant is carried out from the entire top surface of the first redistribution layer. Accordingly, it facilitates the patterning of the first redistribution layer, and no residue is left.

For example, the deposited first redistribution layer is patterned into a first portion 220A using a first mask layer. Thereafter, a second redistribution layer is deposited. The second redistribution layer is patterned into a first portion 230A and a second portion 230B. The first mask layer and the second mask layer have different opening patterns. As a result, the first redistribution layer located over the sensing region or device region 110 (e.g., the second portion 220B shown in FIG. 1C) can be substantially completely removed. Therefore, no residue of the first redistribution layer is left over the sensing region or device region 110. The reliability of the chip package can be prevented from experiencing negative effects due to residue.

Referring to FIG. 2C, the protection layer 250, the openings 260 of the protection layer 250, and the conducting structures 270 may be sequentially formed by steps that are the same as or similar to the steps shown in FIGS. 1E and 1F. Subsequently, a dicing process is performed to form multiple independent chip packages.

In some embodiments, the protection layer 250 is not filled into the first openings 190 so that a void is formed between the first portion 230A and the protection layer 250 within the first openings 190. As a result, when the chip package suffers from a thermal cycle in subsequent processes, the void can serve as a buffer between the protection layer 250 and the first portions 220A and 230A. The void reduces undesirable stress caused by a mismatch of thermal expansion coefficients. The void also prevents the first portion 220A and the first portion 230A from being excessively pulled by the protection layer 250 when the outside temperature or pressure changes drastically. Accordingly, the first portion 220A and the first portion 230A near the conducting pad structure are prevented from being peeled off or even broken. In some other embodiments, the protection layer 250 may partially fill the first openings 190 or fill up the first openings 190.

In some embodiments, the protection layer 250 is in direct contact with the first portion 220A, the first portion 230A, and the second portion 230B. The protection layer 250 is also in direct contact with the first insulating layer 210. In some embodiments, a part of the protection layer 250 is laterally sandwiched between the first portion 220A and the second portion 230B. A part of the protection layer 250 is laterally sandwiched between multiple second portions 230B. In some embodiments, the second portion 230B is partially longitudinally sandwiched between the protection layer 250 and the first insulating layer 210.

In some embodiments, another bonding layer may optionally be formed between the conducting structures 270 and the exposed second portion 230B. For example, the bonding layer may include a nickel layer, a gold layer, another suitable material layer, or a combination thereof.

The aforementioned embodiments can solve the problem of circuit failures in a dense circuit area. In particular, the electromigration phenomenon and/or the Galvanic effect is mitigated or eliminated. Therefore, the quality and reliability of the chip package is greatly enhanced.

Many variations and/or modifications can be made to embodiments of the disclosure, such that the embodiments of FIGS. 1A to 1F may be combined with the embodiments of FIGS. 2A to 2C. For example, a structure as shown in FIG. 2B is provided. Afterwards, steps that are the same as or similar to the steps shown in FIGS. 1D to 1F are performed over the structure as shown in FIG. 2B to form a chip package shown in FIG. 3. In FIG. 3, the second portion 230B is in direct contact with the second insulating layer 240 and the first insulating layer 210. The second portion 230B is partially longitudinally sandwiched between the second insulating layer 240 and the first insulating layer 210.

It should be realized that the chip package in FIG. 3 have the aforementioned advantages and technical effects possessed by the chip package in FIG. 1F and/or FIG. 2C.

To illustrate embodiments of the invention, a chip package with a front side illumination (FSI) sensing device is used herein as an example. However, embodiments of the invention are also applicable to a chip package with a backside illumination (BSI) sensing device. Furthermore, the aforementioned method of forming a chip package is not limited to a chip package with an optical sensing device. It is also applicable to a chip package with a sensing element which is configured to sense biometrics or environmental characteristics, or another suitable chip package.

While the invention has been described by way of example and in terms of the preferred embodiments, it is to be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A chip package, comprising:
a substrate, wherein a sensing region or device region in the substrate is electrically connected to a conducting pad;
a first insulating layer on the substrate;
a first redistribution layer on the first insulating layer, wherein a first portion and a second portion of the first redistribution layer are electrically connected to the conducting pad;
a second insulating layer, wherein the second insulating layer conformally extends on the first insulating layer and covers side surfaces of the first portion and the second portion; and
a protection layer on the second insulating layer, wherein a portion of the second insulating layer is located between the protection layer and the first insulating layer.

2. The chip package as claimed in claim 1, wherein the portion of the second insulating layer is in direct contact with the first insulating layer and the protection layer.

3. The chip package as claimed in claim 1, wherein the portion of the second insulating layer is sandwiched between the first portion and the second portion of the first redistribution layer.

4. The chip package as claimed in claim 1, further comprising a conducting structure, wherein the conducting structure is disposed on the second portion of the first redistribution layer, and a lower portion of the conducting structure is covered by the protection layer and the second insulating layer.

5. The chip package as claimed in claim 1, wherein another portion of the second insulating layer is laterally sandwiched between the protection layer and the first portion of the first redistribution layer.

6. The chip package as claimed in claim 1, wherein the passive element is bonded to the substrate through a bonding structure.

7. A chip package, comprising:
a substrate, wherein a sensing region or device region in the substrate is electrically connected to a conducting pad;
a first insulating layer on the substrate;
a first redistribution layer on the first insulating layer, wherein a first portion of the first redistribution layer is electrically connected to the conducting pad; and
a second redistribution layer, wherein a first portion of the second redistribution layer is located on the first portion of the first redistribution layer, and a second portion of the second redistribution layer is in direct contact with the first insulating layer.

8. The chip package as claimed in claim 7, wherein the second portion of the second redistribution layer longitudinally overlaps the sensing region or the element region.

9. The chip package as claimed in claim 7, wherein the first portion of the first redistribution layer is partially sandwiched between the first insulating layer and the first portion of the second redistribution layer.

10. The chip package as claimed in claim 7, wherein the first portion of the first redistribution layer is partially sandwiched between the conducting pad and the first portion of the second redistribution layer.

11. The chip package as claimed in claim 7, wherein a bottom surface of the second portion of the second redistribution layer is lower than a bottom surface of the first portion of the second redistribution layer, and the bottom surface of the second portion of the second redistribution layer is substantially coplanar with a bottom surface of the first portion of the first redistribution layer.

12. The chip package as claimed in claim 7, wherein a material of the first redistribution layer is different from a material of the second redistribution layer.

13. The chip package as claimed in claim 7, further comprising a second insulating layer, wherein the second insulating layer conformally extends on the first insulating layer, and wherein the second insulating layer covers a side surface of the first portion of the first redistribution layer, a side surface of the first portion of the second redistribution layer, and a side surface of the second portion of the second redistribution layer.

14. The chip package as claimed in claim 13, wherein a part of the second insulating layer is sandwiched between the first portion of the first redistribution layer and the second portion of the second redistribution layer.

15. The chip package as claimed in claim 7, further comprising a protection layer on the second redistribution layer, wherein the protection layer is in direct contact with the first insulating layer, the first redistribution layer and the second redistribution layer.

16. The chip package as claimed in claim 15, wherein a part of the protection layer is sandwiched between the first portion of the first redistribution layer and the second portion of the second redistribution layer.

17. A method for forming a chip package, comprising:
providing a substrate, wherein a sensing region or device region in the substrate is electrically connected to a conducting pad;
forming a first insulating layer on the substrate;
forming a second redistribution layer on the first insulating layer, wherein a first portion and a second portion of the second redistribution layer are electrically connected to the conducting pad;
forming a second insulating layer, wherein the second insulating layer conformally extends on the first insulating layer and covers side surfaces of the first portion and the second portion of the second redistribution layer; and
forming a protection layer on the second insulating layer, wherein a portion of the second insulating layer is located between the protection layer and the first insulating layer.

18. The method for forming a chip package as claimed in claim 17, further comprising forming a patterned first redistribution layer before the formation of the second redistribution layer, wherein a first portion of the first redistribution layer is located between the first insulating layer and the first portion of the second redistribution layer.

19. The method for forming a chip package as claimed in claim 18, wherein the second portion of the second redistribution layer is in direct contact with the first insulating layer.

20. The method for forming a chip package as claimed in claim 18, wherein the first portion of the first redistribution layer extends to directly contact the conducting pad.

21. The method for forming a chip package as claimed in claim 18, wherein a bottom surface of the second portion of the second redistribution layer is lower than a bottom surface of the first portion of the second redistribution layer, and the bottom surface of the second portion of the second redistribution layer is substantially coplanar with a bottom surface of the first portion of the first redistribution layer.

22. The method for forming a chip package as claimed in claim 17, further comprising:
forming an opening in the protection layer and the second insulating layer to expose the second portion of the second redistribution layer; and
forming a conducting structure in the opening, wherein a lower portion of the conducting structure is surrounded by the protection layer and the second insulating layer.
